(19) United States
(12) Patent Application Publication
(10) Pub. No.: US 2026/0343780 A1
(43) Pub. Date: Oct. 29, 2026

(54) SLEEVE INTEGRATED CROSS BAR FOR POWER AND DATA CABLE RETENTION

(71) Applicant: Dell Products L.P., Round Rock, TX (US)

(72) Inventors: JOHN CHARLES DONACHY, Austin, TX (US); ZHAO CHEN, Shanghai (CN); NICHOLAS LENN POTERACKI, Austin, TX (US)

(21) Appl. No.: 19/192,707

(22) Filed: Apr. 29, 2025

(51) Int. Cl. H05K 7/14

(52) U.S. Cl. CPC H05K 7/1491; H05K 7/1489

(57) ABSTRACT

Methods and systems for managing interconnects for data processing systems are provided. To manage the interconnects, a sleeve and pair of brackets may be used. The sleeve may establish a volume by a chassis of the data processing system. The pair of brackets may support a cross bar in the volume. The cross bar may be used to secure some of the interconnects. A filtering bezel may be positioned to filter air that traverses into the volume. The sleeve may include an entrance for the interconnects but that prevents unfiltered air to flow into the volume.

### FIELD

Embodiments disclosed herein relate generally to interconnect management. More particularly, embodiments disclosed herein relate to systems and methods to secure interconnects.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components and the components of other devices may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1A shows a side view diagram illustrating a system in accordance with an embodiment.

FIG. 1B shows a first perspective view diagram illustrating a portion of the system in accordance with an embodiment.

FIG. 1C shows a second perspective view diagram illustrating a portion of the system in accordance with an embodiment.

FIG. 2A shows a side view diagram illustrating a mechanically interlocking side latch assembly in accordance with an embodiment.

FIGS. 2B-2C show perspective view diagram illustrating a clip in accordance with an embodiment.

FIG. 2D shows a perspective view diagram illustrating a spring loaded cross bar in accordance with an embodiment.

FIGS. 2E-2G show perspective view diagrams illustrating attachment of a spring loaded cross bar in accordance with an embodiment.

FIGS. 2H-2I show side view diagrams illustrating a clip in accordance with an embodiment.

FIG. 3A shows a side view diagram of a cable management mount in accordance with an embodiment.

FIG. 3B shows a perspective view diagram of a cable management mount in accordance with an embodiment.

FIGS. 3C-3E show perspective view diagrams of portions of a cable management mount in accordance with an embodiment.

FIG. 3F shows a side view diagram of a cable management mount including a bracket in accordance with an embodiment.

FIGS. 3G-3H show perspective view diagrams of a cable management mount including a bracket in accordance with an embodiment.

FIG. 4 shows a flow diagram illustrating a method in accordance with an embodiment.

FIG. 5 shows a block diagram illustrating a data processing system in accordance with an embodiment.

### DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to methods and systems for managing operation of data processing systems. To provide various services, the data processing system may include various hardware components to perform computations. As part of performing the computations, the hardware components may need to be operably connected to other hardware components of other data processing systems.

To establish such connections, various interconnects such as optical or copper cabling may be used. The interconnects may facilitate communication between various hardware components.

To manage the interconnects, an interconnect management assembly may be used. The interconnect management assembly may be a tool free assembly for routing and securing of interconnects between data processing systems.

The interconnect management assembly may retain interconnects in place one routed, and facilitate efficient changes to interconnects by, for example, enabling relationships between different interconnects to be identified. By doing so, embodiments disclosed herein may reduce a likelihood of interconnects being improperly connected (e.g., thereby not providing desirable operably connectivity), the interconnects being damaged (e.g., by preventing undesired forces to be applied to the cabling, such as cabling being pulled under its own weight to tightly and thereby self damaging), and/or time required to route and secure the interconnects.

In an embodiment, a management system for interconnects to operably connect data processing systems is provided. The management system may include a pair of brackets adapted to attach to a chassis; a sleeve adapted to: partially enclose a volume extending from the chassis and enclosing the pair of brackets, and facilitate routing of the interconnects into the volume; at least one cross bar adapted to: attach to the pair of brackets, and while attached to the pair of brackets, secure at least a portion of the interconnects in the volume.

The management system may also include an air filtering bezel adapted to partially enclose the volume on a side of the volume opposite to the chassis.

The interconnects may not pass into the volume through the air filtering bezel.

The sleeve may include at least one entrance to pass the interconnects into the volume.

The air filtering bezel and the sleeve may define an airflow path to the chassis.

The at least one entrance may be out of the airflow path.

The at least one cross bar may include a plurality of cross bars, and the pair of brackets are adapted to support the plurality of cross bars at different locations with respect to the chassis.

The different locations may correspond to different sleds in the chassis to secure different ones of the interconnects with respect to the different sleds.

The plurality of cross bars may be aligned with one another when supported by the pair of brackets.

Receptacles for attachment of the interconnects may be positioned on the chassis and in the volume.

The sleeve may enclose the volume on four sides, and the chassis may enclose the volume on a fifth side.

The management system may also include a tie adapted to reversibly fixedly secure a portion of the interconnects to the at least one cross bar.

In an embodiment, a data processing system is provided. The data processing system may include a chassis; and a management system as discussed above.

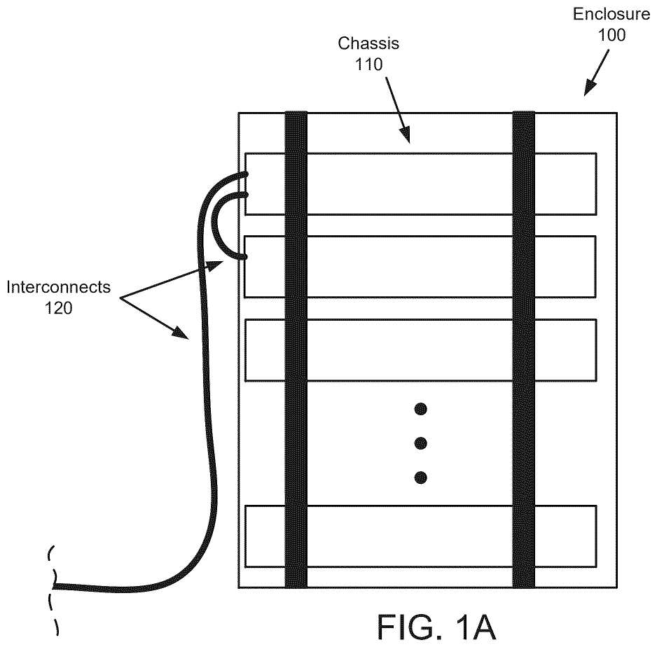

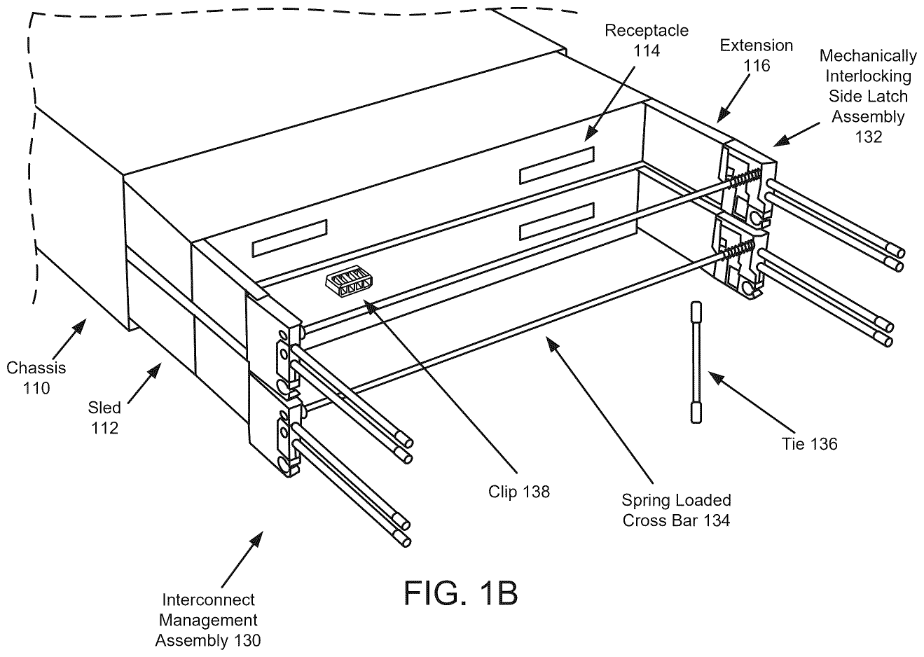

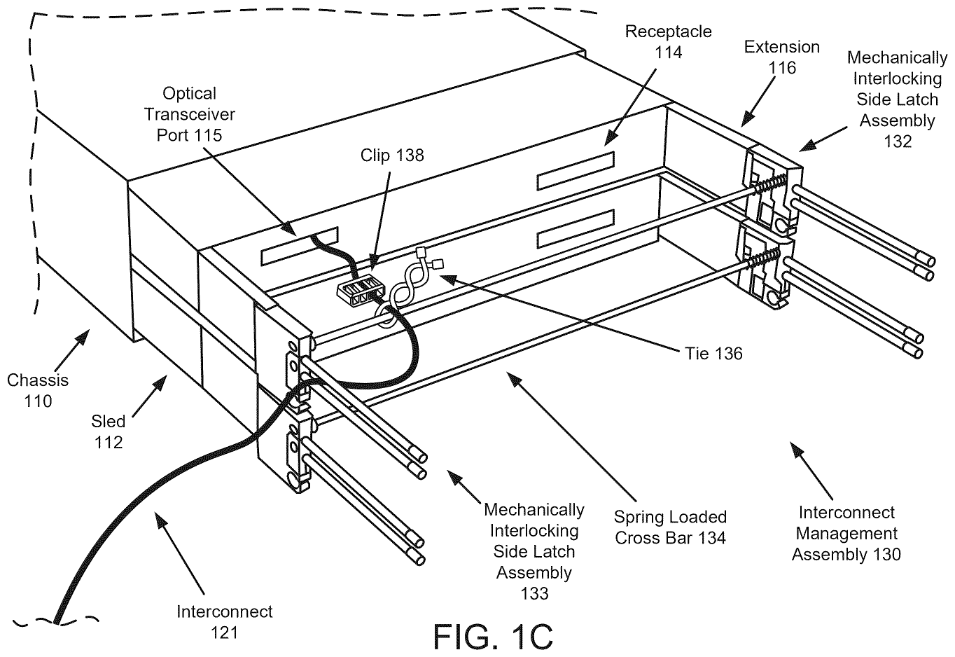

Turning to FIG. 1A, a block diagram of a system in accordance with an embodiment is shown. The system may provide any number and type of computer implemented services.

To provide the computer implemented services, the system may include any number of data processing systems which may cooperatively and/or in isolation provide all, or a portion, of the computer implemented services. To contribute toward the computer implemented services, any of the data processing systems may include any number and type of hardware component.

During their operation, any of the hardware components may need to communicate with other hardware components that are not part of a corresponding data processing system. For example, different data processing systems may include chassis (e.g., 110) such as rack mount cases (e.g., one rack unit (1U), two rack unit, etc.). The enclosures may segregate hardware components of different data processing systems, and facilitate housing of the respective data processing system in various enclosures (e.g., 100, may be a rack system for housing rack mount chassis). In FIG. 1A, an example side view of an enclosure (e.g., 100) is shown, with a front side through which the chassis may be positioned in the enclosure being from the left hand side of the page.

To facilitate communications between the hardware components of the data processing systems and/or with other devices (not shown), the data processing systems may be interconnected using various interconnects 120. Interconnects 120 may include various communication, power, and/or other types of interconnects to facilitate interactions (e.g., communications) between hardware components. The interconnects may be implemented using communication cabling (e.g., optical fibers or other types of optical cabling to facilitate optical communications, coaxial cabling or other types of copper cables, etc.) and/or other types of structures. In FIG. 1A, only a limited number of interconnects 120 are shown. It will be appreciated that a system in accordance with an embodiment may include any number and type of interconnects 120.

Using interconnects 120, the hardware components of the data processing systems may send and receive information. The information may be used, for example, to coordinate activity among various devices, to transmit data required to perform various computations, and/or for other purposes.

However, if interconnects 120 are not connected in a predetermined manner (e.g., establishing connections between various receptacles), become damaged due to physical stress, and/or are otherwise unable to provide their interconnect functionality, then all, or a portion, of the data processing systems may be unable to provide all, or a portion, of their respective functionalities.

In general, embodiments disclosed herein relate to systems, methods, and devices for establishing and maintaining interconnects between components of a systems. To do so, an interconnect management assembly may be used. The interconnect management assembly may facilitate establishment and maintaining of interconnects.

Turning to FIG. 1B, a perspective view illustrating an example interconnect management assembly 130 positioned with respect to chassis 110 in accordance with an embodiment is shown. In FIG. 1B, a front of chassis 110 may be viewed. In the context of a rack system, chassis 110 may slide into and out of the page along rails or other fixation elements of the rack system.

To facilitate establishing operable connections between hardware components positioned in chassis 110 and other components, various receptacles for interconnects 120 may be positioned near the front of chassis 110.

For example, chassis 110 may house any number of sleds (e.g., 112). Each sled may house various hardware components. The receptacles (e.g., 114) may be positioned with the sleds (e.g., 112) near the front of chassis 110. The receptacles may include any number and types of receptacles (e.g., optical, electrical) for establishing connections with other devices via interconnects 120. While illustrated in FIG. 1B as including a limited number of receptacle 114, it will be appreciated that a chassis (or portion thereof) may include any number of receptacles with similar or different placements from those shown in FIG. 1B without departing from embodiments disclosed herein.

To establish the connections, connectors of interconnects 120 may need to be positioned with the receptacles. The interconnects may also need to be routed or otherwise positioned so that similar connections may be established with other receptacles of other data processing systems or other devices (not shown).

To facilitate positioning and maintaining of the positioning of interconnects 120, interconnect management assembly 130 may be used. Interconnect management assembly 130 may be a tool free assembly which may be affixed to a chassis (or portions thereof, in FIG. 1B different portions of interconnect management assembly 130 are illustrated as being affixed to different sleds). When so affixed, interconnect management assembly 130 may assist in routing and maintaining of positioning of portions of interconnects 120.

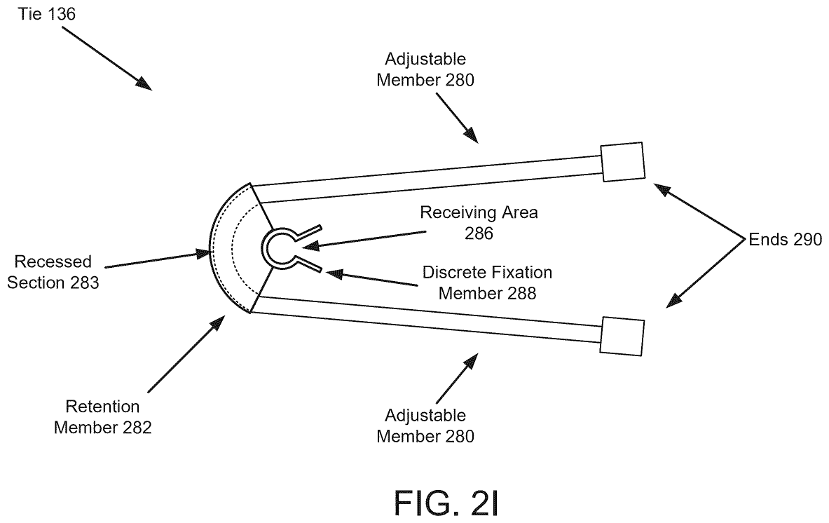

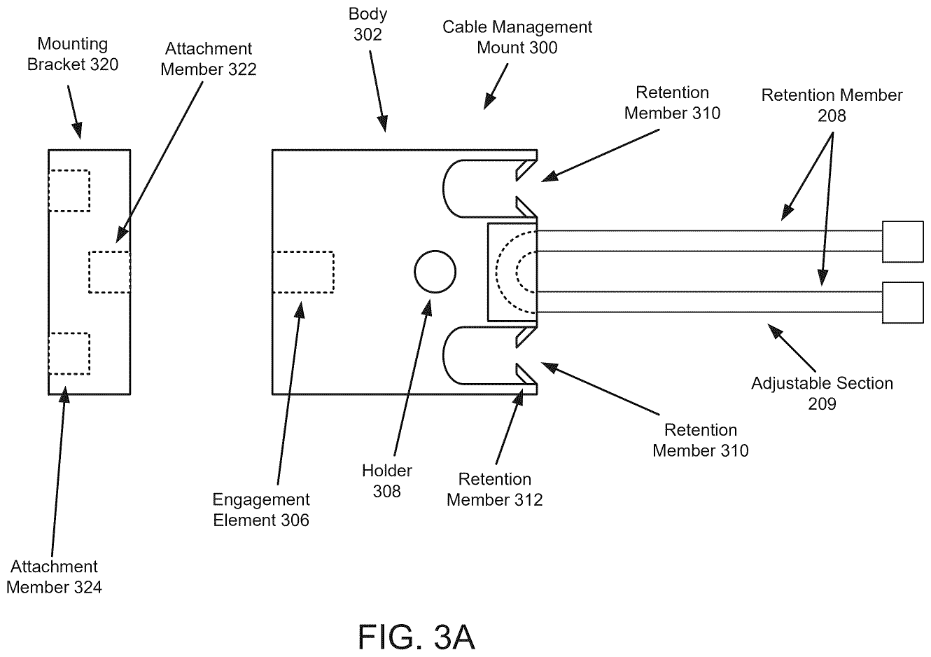

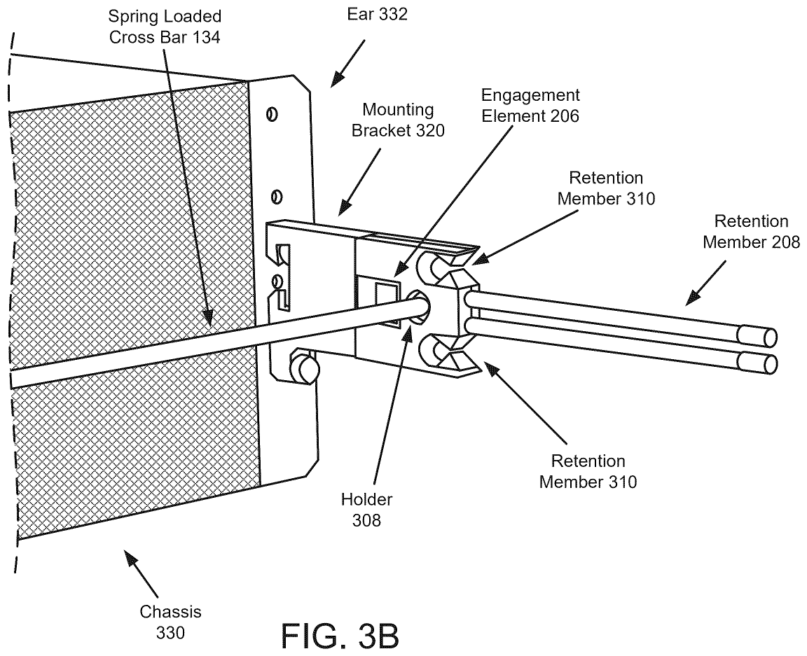

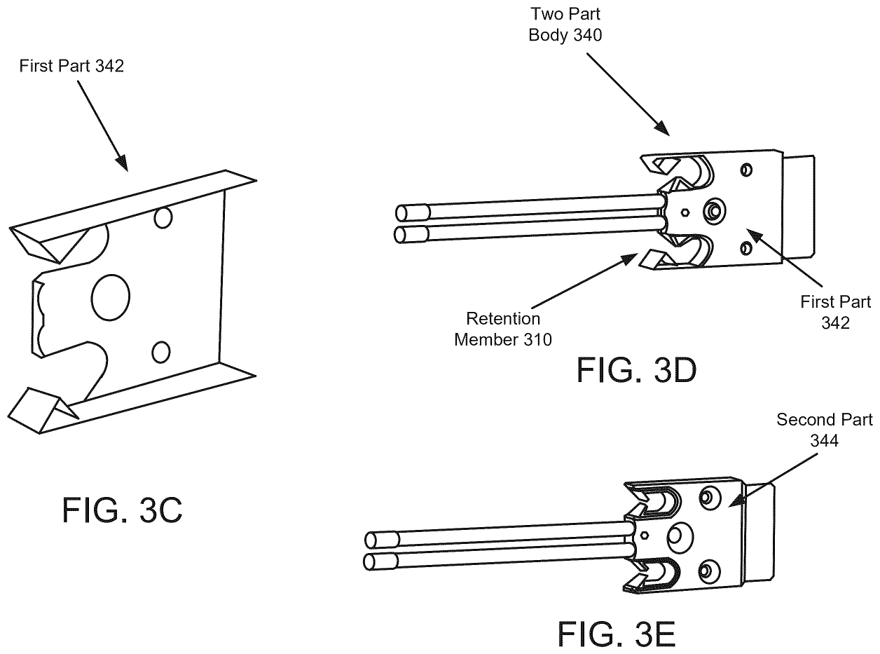

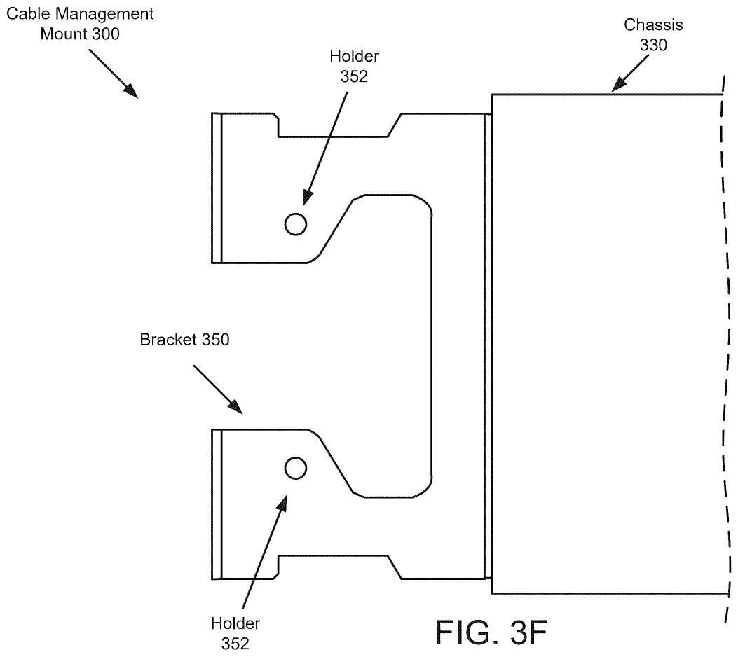

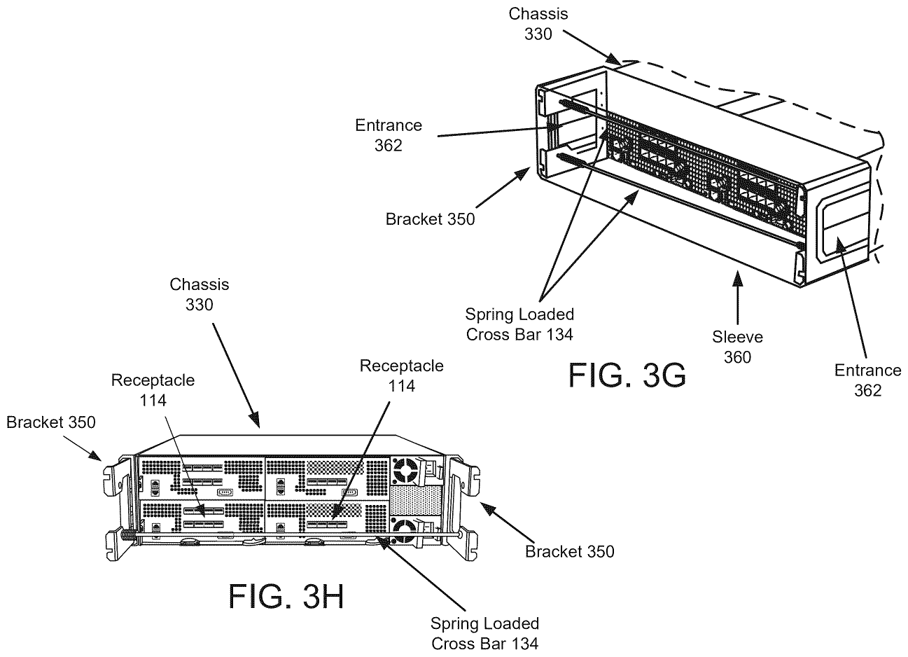

To provide its functionality, interconnect management assembly may include any of mechanically interlocking side latch assembly 132, spring loaded cross bar 134, tie 136, and clip 138. Additionally, interconnect management assembly may include any of the cable management mounts discussed with respect to FIGS. 3A-3H. Each of these components is discussed below.

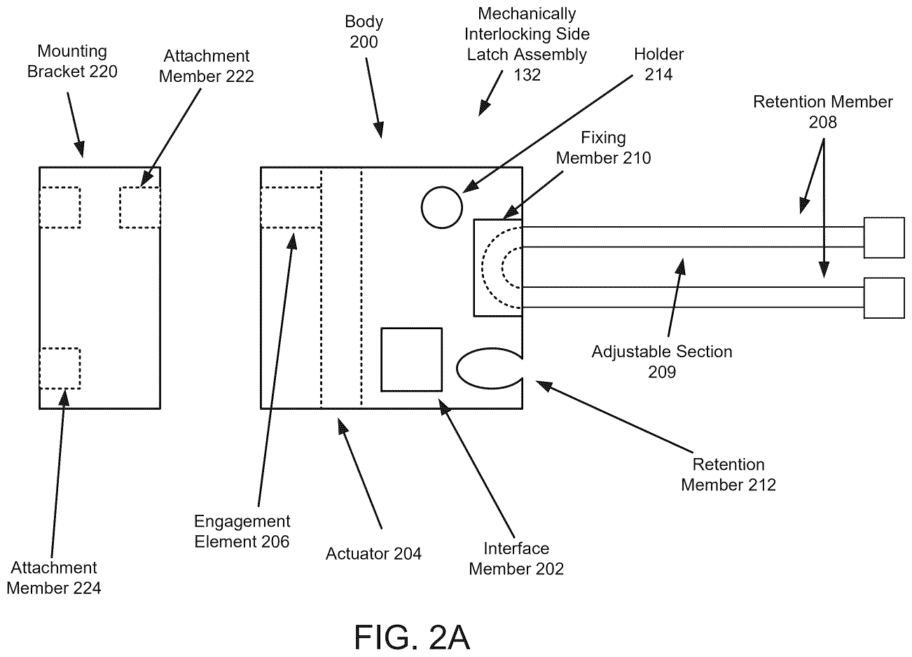

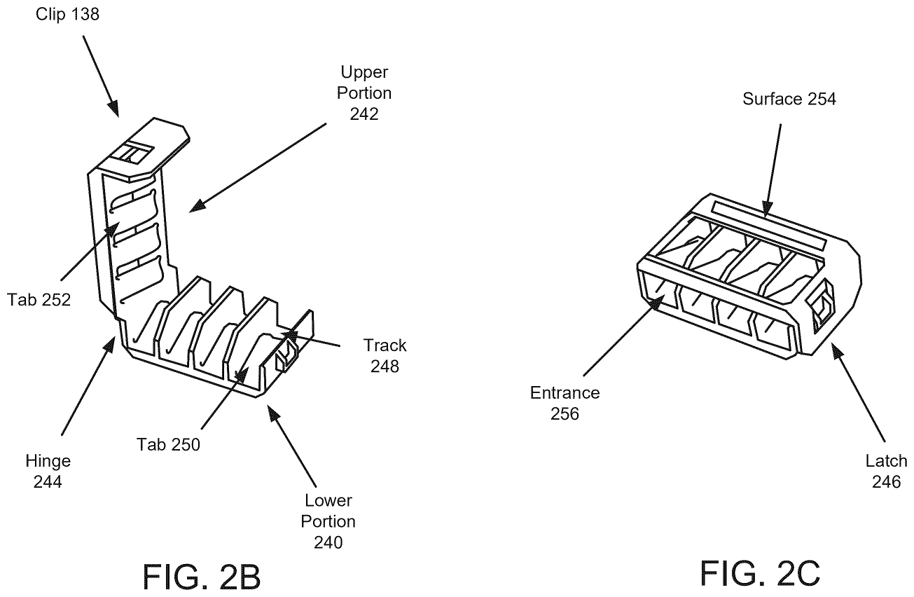

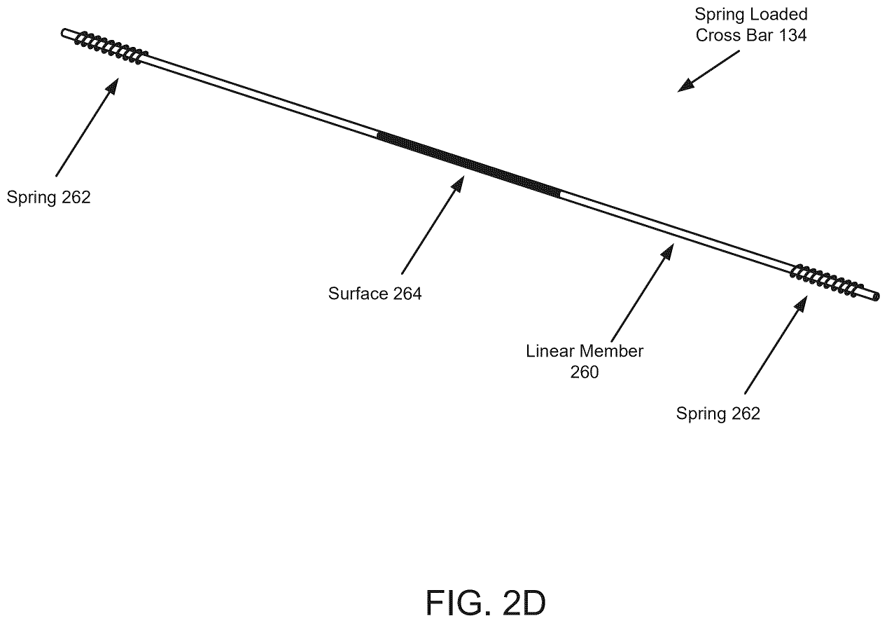

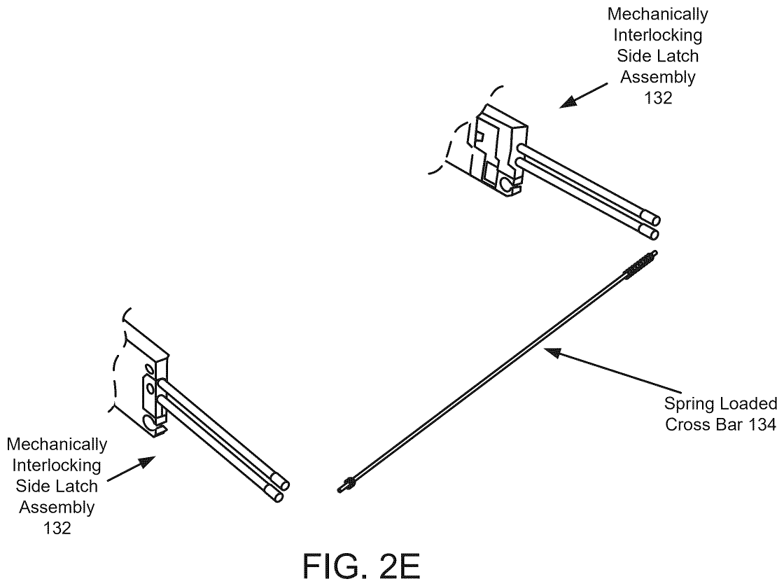

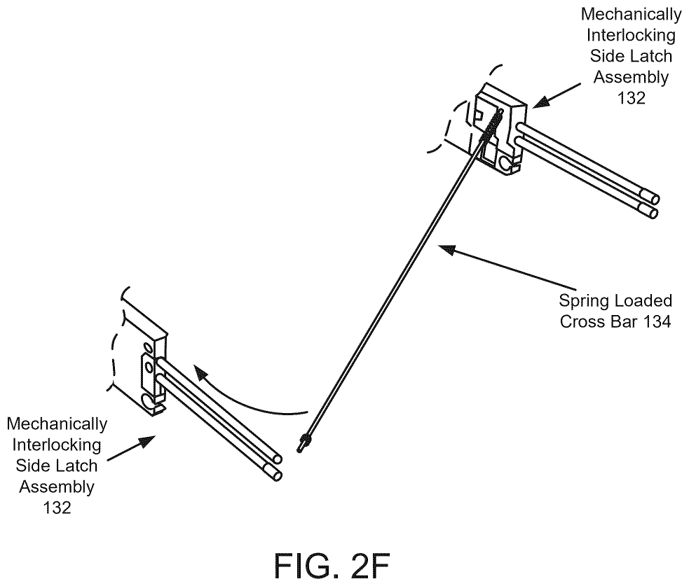

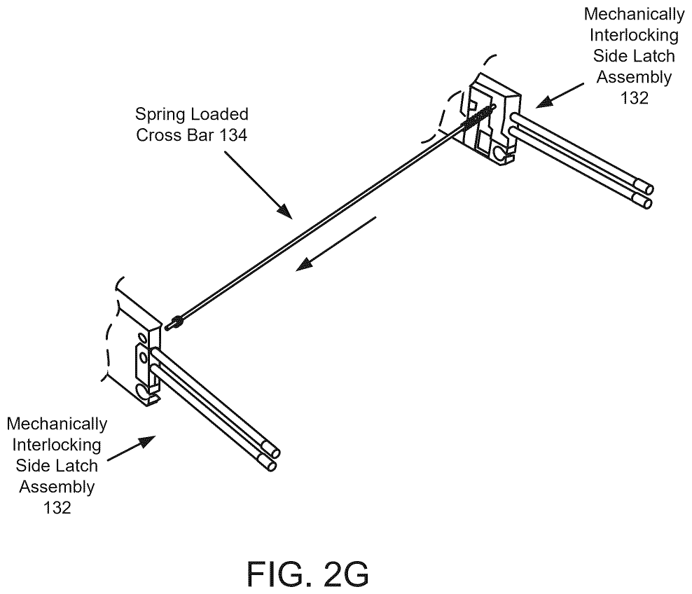

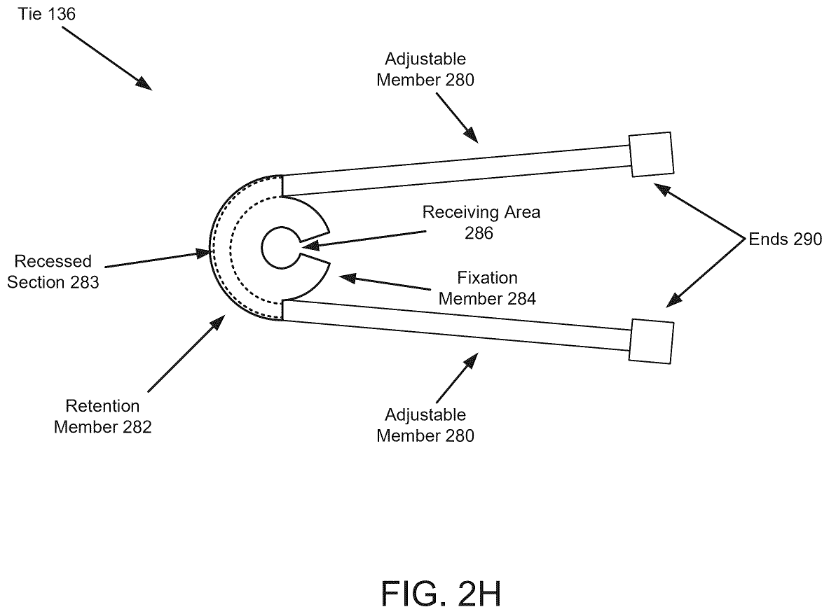

Mechanically interlocking side latch assembly 132 may be adapted to (i) position portions of interconnects 120, (ii) position spring loaded cross bar 134 (in FIG. 1B, two spring loaded cross bars are shown), and (iii) attach directly or indirectly to chassis 110 (in FIG. 1B, mechanically interlocking side latch assembly 132 is shown as attaching to an extension (e.g., 116) which attaches to a sled that in turn is part of chassis 110) to facilitate relative positioning of interconnects with respect to receptacles of chassis 110. Mechanically interlocking side latch assembly 132 may be a tool free assembly. Two mechanically interlocking side latch assemblies may be attached to different sides of a sled, and a spring loaded cross bar 134 may be positioned using the mechanically interlocking side latch assemblies. Refer to FIG. 2A for additional information regarding mechanically interlocking side latch assembly 132. Additionally, refer to FIGS. 3A-3H for additional details regarding cable management mounts which may be used in combination with and/or as a replacement for mechanically interlocking side latch assemblies

Spring loaded cross bar 134 may be adapted to (i) attach to a pair of mechanically interlocking side latch assemblies to be positioned with respect to receptacles of a sled, and (ii) facilitate fixation of portions of interconnects 120 at predetermined locations (e.g., using tie 136). Spring loaded cross bar 134 may also be a tool free assembly, and may be implemented in part using a rod or other structural member. A surface of the structure member may be partially textured to (i) facilitate identification of predetermined locations, and (ii) improve fixation of elements along the structural member. For example, the surface may include various knurled sections to establish interferences which may reduce the likelihood of element affixed to the structural member (e.g., using tie 136) rotating or translating with respect to the structural member. Thus, like mechanically interlocking side latch assembly 132, spring loaded cross bar 134 may also facilitate positioning of other portions of interconnects 120 (e.g., with respect to receptacle 114, sled 112, chassis 110, etc.). Refer to FIGS. 2D-2G for additional details regarding spring loaded cross bar 134.

Tie 136 may be adapted to fixedly place portions of interconnections 120 with respect to spring loaded cross bar 134. To do so, tie 136 may have an adjustable shape to circumscribe both a portion of spring loaded cross bar 134 and a portion of interconnects 120. For example, when the portion of interconnects 120 is positioned on spring loaded cross bar 134, tie 136 may be wrapped around and twisted to establish a loop that is tightened by the twisting. The loop may be tightened, for example, until sufficient pressure is maintained between spring loaded cross bar 134, the portion of interconnects 120, and tie 136 that these components are unlikely to move with respect to one another (e.g., at least while no other forces are applied). In this manner, portions of interconnections 120 may be fixed with respect to spring loaded cross bar 134. While illustrated in FIG. 1B as having a linear shape, it will be appreciated that tie 136 may have other shapes without departing from embodiments disclosed herein. Refer to FIGS. 2H-2I for additional information regarding tie 136.

Clip 138 may be adapted to hold portions of interconnects 120 with respect to other portions of interconnects 120. Additionally, clip 138 may be adapted to limit force applied to the portions of interconnects 120 while maintaining the positioning. Consequently, clip 138 may be usable to maintaining ordering, spacing, and/or other relationships between different portions of interconnects 120. For example, interconnects 120 may include three cables that need to be attached to three different receptacles on chassis 110. Prior to making the connections, the cables may be positioned in clip 138 to define the ordering. Consequently, during installation, a technician or other person tasked with attaching the cables may not need to re-trace the cables to identify the ordering. Accordingly, the cables may be more likely to be attached to the corresponding receptacles. Refer to FIGS. 2B-2C for additional information regarding clip 138.

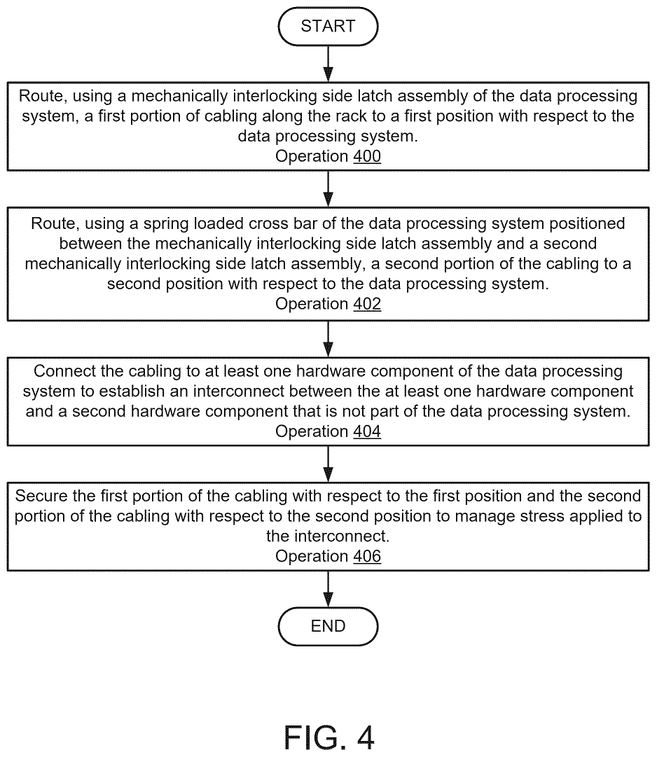

Any devices (and/or components thereof) included in the system shown in FIG. 1B may be implemented using a computing device (also referred to as a data processing system) such as a host or a server, a personal computer (e.g., desktops, laptops, and tablets), a “thin” client, a personal digital assistant (PDA), a Web enabled appliance, a mobile phone (e.g., Smartphone), an embedded system, local controllers, an edge node, and/or any other type of data processing device or system. For additional details regarding computing devices, refer to FIG. 4.

Any of the computing devices may be operably connected to each other (and/or components not illustrated) with a communication system (not shown). In an embodiment, this communication system includes one or more networks that facilitate communication between any number of components (e.g., including others not shown in FIG. 1). The networks may include wired networks and/or wireless networks (e.g., and/or the Internet). The networks may operate in accordance with any number and types of communication protocols (e.g., such as the internet protocol). Any of interconnects 120 may facilitate communication via the networks. For example, any of interconnects 120 may operably connect the hardware components of a data processing system that are position in chassis 110 to a switch (e.g., top of rack) or other network device. The network device in turn may route or otherwise direct the communications to establish communication channels.

While illustrated in FIG. 1B as including a limited number of specific components, a system in accordance with an embodiment may include fewer, additional, and/or different components than those illustrated therein.

As discussed above, interconnect management assembly 130 may be used to manage positioning of interconnections 120 with respect to chassis 110. Turning to FIG. 1C a second perspective view illustrating interconnect management assembly 130 positioned with respect to chassis 110 in accordance with an embodiment is shown. The view in FIG. 1C may be similar to that shown in FIG. 1B. However, an interconnect 121 is illustrated in FIG. 1C to show an example of use of interconnect management assembly 130.

Now, consider an example scenario where an optical transceiver is positioned in one of the sleds of chassis 110. To facilitate communications, an optical fiber or other communication cable may be connected to optical transceiver port 115 of the optical transceiver. The communication cable may be sensitive to damage but also flexible and not self-supporting. To maintain the positioning of interconnect 121, clip 138 may be used to position interconnect 121 with respect to other interconnects (not shown in this example). For example, two transceiver ports (e.g., including 115) may be positioned next to one another and two different communication cables may need to be connected to each. The ordering between these cables may be maintained by positioning both in clip 138 and fixedly securing the relative positioning of portions of the two communication cables.

To limit sheer forces applied to interconnect 121 (e.g., due to gravity) and optical transceiver port 115, a portion of interconnect 121 may be run over spring loaded cross bar 134 and may be secured in place using tie 136. As seen in FIG. 1C, the shape of tie 136 may change to circumscribe and fixedly place interconnect 121 proximate to spring loaded cross bar 134.

To route interconnect 121 away from the front of chassis 110, interconnect 121 may be positioned proximate to mechanically interlocking side latch assembly 133. Once so positioned, features of mechanically interlocking side latch assembly 133 may fix the corresponding portion of interconnect 121 in place.

The remaining portion of interconnect 121 may then be run along a rack system or other structural support for chassis 110. In this manner, interconnect 121 may be routed to optical transceiver port 115 using a tool free process. Accordingly, a person tasked with making such connections may be less likely to make improper connections, may be able to complete the process more quickly (e.g., when compared to tool based processes), and may result in a routed environment that is more easily understood by other people (e.g., interconnect routings more easily understood via visual inspection).

Turning to FIG. 2A, a side view diagram showing mechanically interlocking side latch assembly 132 in accordance with an embodiment is shown. As noted above, mechanically interlocking side latch assembly 132 may be a tool free component for securing interconnects with respect to chassis to, for example, prevent damage to cabling, organizing the cabling, etc.

To provide its functionality, mechanically interlocking side latch assembly 132 may include body 200, interface member 202, actuator 204, engagement element 206, retention member 208, fixing member 210, retention member 212, holder 214, mounting bracket 220, attachment member 222, and attachment member 224. Each of these components is discussed below.

Body 200 may be a structural member. Generally, body 200 may be substantially rectangular in shape. Body 200 may have a height (e.g., top to bottom in FIG. 2A) that is equal to or less than a size of a sled (e.g., 1U) or a chassis (e.g., 1U, 2U, etc.).

Interface member 202 may be a structural member adapted to receive force (e.g., from a user) and use the force to initiate actuation of actuator 204. For example, interface member 202 may be implemented using a button (or other type of force receiving member) positioned on a surface of body 200. When force is applied to the button (e.g., by a technician pushing the button), a coupling or other mechanical interconnect (not shown) may transmit the force to actuator 204 to cause actuator 204 to actuate. As will be discussed below, actuation of actuator 204 may allow body 200 to separate from mounting bracket 220.

Actuator 204 may be adapted to selectively facilitate disengagement of body 200 from mounting bracket 220. Mounting bracket may include one or more attachment members (e.g., 222) adapted to establish an interference with corresponding engagement elements 206 positioned with body 200. When the interference is established, body 200 may be fixedly secured to mounting bracket 220. For example, an attachment member may include a recess or other features into which a corresponding engagement element may engage thereby establishing the interference (e.g., ramped surfaces only being on one side so that once the interference is established it will be maintained without movement of the attachment members or the engagement members). In FIG. 2A, actuator 204, engagement element 206, and attachment member 224 are drawn in dashing to indicate that these features may be within other components or otherwise obscured from view in FIG. 2A.

To release the interference, actuator 204 may reposition the engagement element by, for example, rotating them away from each other, rotating them outward, or otherwise moving them so that the interference between the attachment member and the engagement member is relieved. For example, engagement element 206 may include a proud feature (e.g., a ramp) which may slide into attachment member 222 and establish the interference. The ramp may then be rotated away from attachment member 222 (e.g., outward from the page) relieving the interference. While relieved, body 200 may be moved away from mounting bracket 220 to detach body 200 from mounting bracket 220.

Mounting bracket 220 may facilitate securing of body 200 with respect to a sled, chassis, or other portion of a data processing system. Mounting bracket 220 may be a structural element, and may include attachment members (e.g., 224) for attaching mounting bracket 220 to other structures. The attachment members (e.g., 224) may be tool less, and may be implemented using, for example, thumb screws, nuts, and/or other fixation elements that may be used to secure mounting backet 220 to other structures without using tools.

When mounting bracket 220 and body 200 are fixedly secured to a sled, chassis, etc., a spring loaded cross bar (e.g., 134) may be secured to it (and another mechanically interlocking side latch assembly 132) using holder 214. Holder 214 may be implemented using an aperture through body 200. The size, shape, and other characteristics of holder 214 may be adapted to facilitate tool free insertion of a portion of the spring loaded cross bar in holder 214. When so inserted, the spring loaded cross bar may self-center (or otherwise adjust its positioning) with respect to the pair of mechanically interlocking side latch assemblies. Refer to FIGS. 2D-2H for additional information regarding spring loaded cross bars and interactions with mechanically interlocking side latch assembly 132.

Retention member 208 may facilitate securing of portions of interconnects with respect to body 200. To do so, retention member 208 may include adjustable sections (e.g., 209) that may be bent, twisted, and otherwise reshaped by application of force. Once adjusted, the adjustable sections may retain the new shape until additional force is applied to them. Retention member 208 may be implemented using, for example, a coated length of wire (or wire strands). The coating may be plastic, rubber, or other material. Caps or other structures may be affixed to the ends of the length of wire.

Retention member 208 may be fixed to body 200 via fixing member 210. Fixing member 210 may include a recessed section of body 200. The recessed section may be U-shaped so that two portions of retention member 208 may emerge from a same side of body 200. Fixing member 210 may also include bolts, screws, plates, and/or or other structures for securing retention member 208 in the recessed section.

To secure a portion of an interconnect, the portion may be positioned between two portions of retention member 208. The two portions of retention member 208 may then be moved to circumscribe the portion of the interconnect. The two portions of retention member 208 may be twisted to establish an enclosing loop which may tighten until the loop is reduced in size and applies pressure (or at least establishes surface contact) to the portion of the interconnect. The pressure and/or surface contact may retain the portion of the interconnect in place.

While shown as a unitary structure in FIG. 2A, it will be appreciated that two separate retention members (e.g., capped lengths of wire) may be attached to body 200 via fixing member 210 without departing from embodiments disclosed herein. Likewise, the unitary structure may be logically divided into two retention members without departing from embodiments disclosed herein.

Like retention member 208, retention member 212 may also retain portions of interconnects in place. To do so, retention member 212 may be implemented with hole through body 200. The hole may be positioned near an edge of body 200 so that portions of interconnects may be moved into the hole through the edge. Consequently, cabling of the interconnects may not need to be threaded through the hole but may instead be moved in through the open side of the hole through body 200.

While shown in FIG. 2A by way of example, assemblies usable to route and secure interconnects may take other forms. Refer to FIGS. 3A-3H for additional information regarding assemblies usable to route and secure interconnects.

Turning to FIGS. 2B-2C, perspective view diagrams of clip 138 in accordance with an embodiment are shown. In the figures the same perspective is used. However, in FIG. 2B, clip 138 is illustrated in an open configuration while in FIG. 2C clip 138 is illustrated in a closed configuration.

As discussed above, clip 138 may be adapted to maintain spatial positioning of various interconnects. To do so, clip 138 may include lower portion 240, upper portion 242, hinge 244, latch 246, track 248, tab 250, tab 252, surface 254, and entrance 256. Each of these components is discussed below.

Lower portion 240 and upper portion 242 may be structural components for positioning interconnects. Each may be implemented using, for example, plastic injection molded plastic parts.

Upper portion 242 may be connected to lower portion 240 via hinge 244. Hinge 244 may be an integrated hinge (e.g., part of upper/lower portions) or discrete (the hinge may be a live hinge). Hinge 244 may enable upper portion 242 and lower portion 240 to rotate towards/away from each other.

When rotated towards each other, latch 246 may enable upper portion 242 to be fixed in position with lower portion 240 (e.g., until latch 246 is released via application of pressure). When so positioned, tracks (e.g., 248) through clip 138 may be established. Each track may enable a corresponding interconnect to traverse through clip 138 via the track. Generally, the size (e.g., cross sectional opening) of each track may be set so that a diverse array of interconnect diameters may fit through the track.

To route interconnects, the different interconnects may be positioned in different tracks while clip 138 is open as illustrated in FIG. 2B. Once routed, clip 138 may be closed as illustrated in FIG. 2C to secure the relative positioning of the different interconnects with respect to one another.

Tabs (e.g., 250, 252) may be positioning in each track. The tabs may be implemented using, for example, tongue retention tabs. The tongue retention tabs may automatically apply force to at least two sides of an interconnect positioned in the track to center the interconnect in the track (e.g., thereby reducing the likelihood of high force being applied to the interconnect by lower portion 240 or upper portion 242). The tabs may be adapted to apply less force than is required to damage the interconnect. Consequently, the interconnect may be allowed to move within the track by the tab when sufficient external force is applied to the interconnect. In other words, when sufficient force is applied, a tab may deform to relieve the counter force applied to the interconnect to reduce the likelihood of tab-applied force from damaging the interconnect.

To facilitate long term management of the interconnects, surface 254 may be adapted to identify the interconnects in each of the corresponding tracks. For example, surface 254 may include modifiable texturing. The texturing may be modified by a technician or other person during interconnect routing so that the interconnect in each track may be identified using the modified texturing at other points in time.

For example, surface 254 may include raised pins (or other features) that may be removed or otherwise modified. Surface 254 may also support direct labeling using other modalities.

Similarly, any of the tracks may be labeled or otherwise made identifiable. Additionally, the non-symmetric structure of clip 138 may enable different tracks to be identified directly. Consequently, the corresponding interconnects and/or functions/requirements for the interconnects may be identified.

For example, in some cases components of data processing systems to which the interconnects connect may need to be replaced. Prior to replacement, clip 138 may be attached to a set of interconnects that are connected to a component. The set of interconnects may then be disconnected and the component may be replaced. Once replaced, the relative ordering of the interconnects as documented by clip 138 may be used to identify where each of the set of the interconnects are to be attached to the replaced component.

While illustrated in FIGS. 2B-2C as including four tracks, it will be appreciated that clip 138 may include fewer or more tracks without departing from embodiments disclosed herein.

Turning to FIG. 2D, a perspective view diagram of spring loaded cross bar 134 in accordance with an embodiment is shown. To provide its functionality, spring loaded cross bar 134 may include linear member 260, springs (e.g., 262), and surface 264. Each of these components is discussed below.

Linear member 260 may be structural component having a length adapted to span two mechanically interlocking side latch assemblies. The length may be greater than the distance between the mechanically interlocking side latch assemblies when the mechanically interlocking side latch assemblies are attached to a sled, a chassis, etc.

Linear member 260 may be tubular in shape or may have other shapes, and may have a cross section adapted to be inserted into holders (e.g., 214) of the mechanically interlocking side latch assemblies.

Springs (e.g., 262) may be anchored to portions of linear member 260 near the ends of linear member 260. The positioning may be adapted so that the springs center spring loaded cross bar 134 with respect to the mechanically interlocking side latch assemblies. Refer to FIGS. 2E-2G for additional details regarding centering of spring loaded cross bar 134.

Surface 264 may be a portion of the surface of linear member 260, and may include texturing or other surface features to establish desired frictional coefficients with structures in contact with surface 264. For example, surface 264 may be a knurled surface to establish some level of interference between surface 264 and structures in contact with surface 264. While illustrated in FIG. 2D as being a continuous surface, it will be appreciated that any number of discrete surfaces of linear member 260 may be textured to establish different textured regions.

The textured regions may be adapted to also facilitate positioning of other components. For example, the texturing may be applied in a manner that is complimentary to receptacles of data processing systems. Consequently, interconnects may be positioned on linear member 260 using the texturing to align the interconnects with corresponding receptacles. Once so aligned, ties may be used to fixedly secure the interconnects to spring loaded cross bar 134. Other structures (e.g., clips) may be similarly fixedly secured to spring loaded cross bar 134.

Consequently, alignment of interconnects with receptacles may be improved (or at least the difficulty of doing so such as cognitive load on technicians) may be reduced.

While illustrated in FIG. 2D as having springs near both ends of linear member 260, it will be appreciated that one of the springs may be replaced with a stop or other structure without departing from embodiments disclosed herein (e.g., in FIGS. 2E-2G, spring loaded cross bar 134 is illustrated as including a stop on one end (e.g., left hand side of each sheet) rather than a spring.

Turning to FIGS. 2E-2G, perspective view diagrams of spring loaded cross bar 134 positioned with a pair of mechanically interlocking side latch assemblies in accordance with an embodiment is shown. In FIGS. 2E-2G, the perspective is the same in each figure, and each figure corresponds to a part of an attachment process of spring loaded cross bar 134 with the pair of mechanically interlocking side latch assemblies.

Turning to FIG. 2E, to insert spring loaded cross bar 134, a first end of the linear member with a spring may be inserted into a holder (e.g., 214) on one of the mechanically interlocking side latch assemblies. In FIG. 2E, the end on the right hand side of the page is shown as being moved an inserted into the holder by the arrow with the curved tail.

Turning to FIG. 2F, once the first end is inserted, pressure may be applied to compress the spring near the first end to move the first end through the holder. Consequently, the other end of the linear member may be able to be moved into alignment with the holder of the other mechanically interlocking side latch assembly, as illustrated by the arrow with the curved tail.

Turning to FIG. 2G, while the second end of the linear member is aligned with the holder of the other mechanically interlocking side latch assembly, the pressure may be released thereby enabling the spring to center spring loaded cross bar 134 between the two mechanically interlocking side latch assemblies. Consequently, the second end may be moved into the other holder until the stop reaches the other mechanically interlocking side latch assembly. Accordingly, spring loaded cross bar 134 may be secured to the pair of mechanically interlocking side latch assemblies.

Once secured, various interconnects or other structures may be secured to spring loaded cross bar 134 using ties or other structures. Refer to FIGS. 2H-2I for additional information regarding ties.

Turning to FIG. 2H, a first side view diagram of tie 136 in accordance with an embodiment is shown. Tie 136 may be an example embodiment of a self-retaining retention member. As discussed with respect to FIG. 1B, tie 136 may be used to secure portions of interconnects to other components of the system. To do so, tie 136 may include adjustment member 280, retention member 282, recessed section 283, fixation member 284, and receiving area 286. Each of these components is discussed below.

Adjustable member 280 may be adapted to reversibly fixedly secure components of the system of FIG. 1B to other components. To do so, adjustable member 280 may be adapted to change its shape to (i) circumscribe at least two components, and (ii) tighten around the at least two components to press the at least two components against each other (e.g., to establish sufficient friction so that the pressed sections of the at least two components are unlikely to move unless additional force is applied to them).

Adjustment member 280 may be implemented using, for example, a linear core formed using a metal core (or multi-strand core) or other material. The metal core may be implemented using a wire (or multiple strands), tube, or other metal element. The metal core may be adapted to resist deformation, and adjust its shape when sufficient force is applied (e.g., above a threshold level that is higher than forces that interconnects are likely to place on it). In this manner, the metal core may be wrapped around to components and then twisted together.

The metal core may be covered in plastic, rubber, or other material. Caps or other structures may be positioned at the ends (e.g., 290) of the metal core. The caps may, for example, reduce the likelihood of the metal core escaping the covering layer, reduce likelihood of damage occurring (e.g., may increase surface area so that sharp ends of the metal core are unlikely to damage other components), and/or may perform other functions.

To secure adjustable member 280 to other components, retention member 282 may attach to adjustable member 280 and may include features for attaching to complementary structures such as spring loaded cross bars.

To facilitate attachment to adjustable member 280, retention member 282 may include recessed section 283. Recessed section 283 may be implemented using a trough or through hole having a shape that is complementary to adjustable member 280. The complementary shape may retain adjustment member 280 with retention member 282, unless sufficient force is applied to separate the two. Generally, the force required may be set so that a technician or other person may be required to apply such force.

To facilitate attachment of retention member 282 to other components, fixation member 284 may facilitate (i) insertion of a portion of another component into receiving area 286, and (ii) fixedly securing the portion in receiving area 286. For example, receiving area 286 may have a shape that is complementary to the portion of the component (e.g., for a spring loaded cross bar, receiving area 286 may be tube shaped). Fixation member 284 may be adapted to adjust its shape to facilitate insertion of the portion of the other component in receiving area 286. For example, fixation member 284 may be formed of a plastic, rubber, or other material that may be deformable but also having some elasticity so that it tends to return to a predetermined shape.

Once inserted into receiving area 286, fixation member 284 may return to a predetermined shape that (i) establishes an interference with the inserted component, (ii) presses against the inserted component to increase friction to a predetermined level, and/or otherwise cause fixation member 284 to resist reorientation with respect to the component due to forces applied to the component/tie 136. Consequently, once the component is placed, the ends of the adjustable member 280 may be less likely to move (which may cause interconnects positioned with them to fall out).

Retention member 282 may be unitary structure (e.g., over molded) with adjustable member 280, a separate structure (e.g., a molded part), or multiple separate pieces (e.g., retention member 282 may be formed from multiple pieces that may snap together (or otherwise fixedly secure to one another).

Additionally, retention member 282 may be formed multiple different material, further described with respect to FIG. 2I below.

Turning to FIG. 2I, a second side view diagram of tie 136 in accordance with an embodiment is shown. In contrast to the view shown in FIG. 2H, in FIG. 2I retention member 282 is illustrated as being formed using at least two materials. For example, retention member 282 may be formed from plastic, rubber, etc. However, to improve securing of retention member 282 to other structure, a discrete fixation member (e.g., 288) may be attached to retention member 282.

Discrete fixation member 288 may be formed from a metal or other high elasticity material, and may be adhered to retention member 282. Discrete fixation member 288 may, by virtue of its high elasticity, may be better able to survive multiple cycles of deformation to facilitate insertion of various portions of components in receiving area 286. Additionally, the extended portions of discrete fixation member 288 may be more easily manipulated by a technician or other person.

Thus, using the system as shown in FIGS. 1A-2I, embodiments disclosed herein may facilitate routing and securing of interconnects. To facilitate routing and securing of interconnects in a variety of scenarios, various assemblies such as cable management mounts (e.g., 300) as illustrated by way of example in FIGS. 3A-3H may be used. These assemblies may be used in combination with any of the components shown in FIGS. 1A-2I to route and secure cables in, for example, specialized environments (e.g., 1U server environments, telecommunication equipment environments, etc.) that may impose physical and/or access restrictions on interconnects.

Turning to FIGS. 3A-3B, diagrams of a cable management mount (e.g., 300) in accordance with an embodiment are shown. In FIG. 3A, a side view diagram of cable management mount 300 is shown, and in FIG. 3B, a perspective view of cable management mount 300 attached to a chassis is shown.

To facilitate routing and securing of interconnects in 1U environment, telecommunication system environments, or other space limited environments, cable management assembly 300 may be used. Cable management assembly 300 may be sized to match 1U environments (e.g., have a height smaller than a 1U chassis, top to bottom of the page in FIG. 3A). Generally, cable management assembly 300 may be symmetric so that it may be attached to either side of a chassis and may be rotated without change in its functionality.

To provide its functionality, cable management assembly 300 may include body 302, engagement element 306, holder 308, retention member 310, retention member 312, retention member 208, and/or mounting bracket 320. Each of these components is discussed below.

Body 302 may be similar to the body discussed with respect to FIG. 2A. However, the height of body 302 may be reduced to be smaller than the height of a 1U chassis.

Holder 308 may be similar to the holder discussed with respect to FIG. 2A. To facilitate insertion of spring loaded cross members, holder 308 may be implemented with a conical through hole so that the hole may be larger than the diameter of the cross bar at the surfaces of body 302, and may reduce in diameter at the midpoint through body 302 to be approximately the diameter of the cross bar. The conical shape of holder 308 may enable the cross bar to be inserted while not orthogonal to the surface of body 302 (e.g., similar to as shown in FIG. 2F, where spring loaded cross bar 134 is inserted while at an angle).

A pair of retention member 310 may be positioned on either side of retention member 208. Each of the pair may be implemented with a recess in body 302 so that interconnects may slide into retention member 312 from the side (as opposed to being required to be threaded through length wise). Retention member 310 may include retention members (e.g., 312), which may be implemented using saw tooth shaped plastic protrusions that tend to hold interconnects in retention member 310 (and/or other structures to retain interconnects in retention member 310).

To facilitate attachment of body 302 to other structures, engagement element 306 may reversibly secure itself to attachment member 322. Engagement element 306 may be implemented, for example, with a release lever (which may be actuated by a person to release body 302 from mounting bracket 320) or similar structure, a return element such as a torsion spring that tends to return the release lever to a first position, and an attachment element that is actuated via the release lever. The attachment element may establish an interference that secures body 302 to mounting bracket, and that is dissipated when the release lever is actuated.

Thus, body 302 may be attached to and released from mounting bracket 320 without use of tools.

Mounting bracket 320 may, like the mounting bracket discussed with respect to FIG. 2A, be attached to various structures in a tool free manner. For example, mounting bracket 320 may include thumb screws or other structures that enable mounting bracket 320 to be attached to other structures. For example, in FIG. 3B, mounting bracket 320 is illustrated as being attached to ear 332 of chassis 330. However, it will be appreciated that mounting bracket may be attached to other portions of the chassis.

As shown in FIGS. 3A-3B, body and other portions of cable management mount 300 may be implemented using various formed parts. However, it will be appreciated that cable management mount 300 may be implemented using multiple formed parts.

Turning to FIGS. 3C-3E, perspective view diagrams of portions of cable management mount 300 in accordance with an embodiment are shown. In FIG. 3C, a perspective view of a first part of cable management mount 300 in accordance with an embodiment is shown. In FIG. 3D, a front side perspective view of cable management mount 300 in accordance with an embodiment is shown. In FIG. 3E, a rear side perspective view of cable management mount 300 in accordance with an embodiment is shown.

Cable management assembly 300 may be implemented using a two part body (e.g., 340). Two part body 340 may include a first part 342 and a second part 344. First part 342 may be implemented using a formed metal sheet or other structure that has mechanical properties (e.g., strength, elasticity, etc.) to retain interconnects in retention members (e.g., 310). For example, as seen in FIG. 3C, the metal sheet may be formed to establish side walls of the retention members.

Two part body 340 may also include second part 344. Second part may be formed of a plastic or other material, and to which first part 342 may clip or otherwise attach. Various portions of first part 342 may establish interferences with second part 344 when the two are positioned with one another, such as shown in FIGS. 3D-3E, or may be secured using securing elements such as screws, bolts, and/or other structures.

By using two part formed from materials with different properties, thinner sections of the assembly may be less likely to break thereby enabling the assembly to be used in environments where real estate is at a premium. For example, as seen in FIGS. 3D-3E, the thin sidewalls formed from metal may allow the retention members to have a larger area in which to secure interconnects (e.g., in contrast, the sidewalls of the retention members may be required to be of thicker size if formed entirely from plastic similar to second part 344, thereby reducing the size of the area of the retention members in which interconnects may be positioned.

To facilitate use of cable management mounts in telecommunication environments (or other challenging environments), cable management mounts may be shaped and include features to enable interconnect routing and securing in such environments.

Turning to FIGS. 3F-3H, diagrams showing examples of a cable management mount usable in specialized environments (e.g., telecommunication, industrial, etc.) in accordance with an embodiment is shown. In FIG. 3F, a side view diagram of the cable management mount attached to a chassis in accordance with an embodiment is shown. In FIG. 3G, a perspective view diagram of the cable management mount attached to the chassis in accordance with an embodiment is shown. In FIG. 3H, a rear perspective view diagram of the cable management mount attached to the chassis in accordance with an embodiment is shown.

To facilitate routing and securing of interconnects, cable management mount 300 may include bracket 350. Bracket 350 may be adapted to (i) secure and route interconnects, and (ii) secure filtering sleeves (e.g., 360), bezels, and/or other structures usable to manage operation of data processing systems in challenging environments (e.g., dusty, high/low temperatures, etc.). To do so, bracket 350 may be adapted to attached to chassis 330 via various attachment elements (not shown, may include bolt holes, bolts, etc.). Chassis 330 may include an enclosure for storing hardware components of a data processing system.

Bracket 350 may also include at least one holder 352 (may be similar to holder 308) usable to facilitate securing of spring loaded cross bars (which in turn may be used to route/secure interconnects) with respect to chassis 330. As seen in FIG. 3G, bracket 350 may have a 2U height (e.g., and width to secure to ears or other portions of chassis), and the holders (e.g., 352) may be positioned so that corresponding spring loaded cross bars are positioned with respect to different sleds positioned in chassis 330. Consequently, different interconnects may be positioned and secured with respect to various receptacles (e.g., 114) positioned on the chassis (and/or sleds therein).

To manage the challenging environments in which the chassis may be positioned, sleeve 360 may establish a volume for filtering air taken into chassis 330. For example, sleeve 360 may be implemented using a linear extension that may be secured in place using the brackets (e.g., at least in part), chassis, and/or other components of the data processing system. In turn, sleeve 360 may support a filter (e.g., filtering bezel, not shown) so that air drawn into the area bound by sleeve 360 is filtered of particulates or other undesired materials. The filter bezel may take on any form, but may generally now allow for interconnects to enter the volume.

To enable interconnects to be positioned in the volume bounded by sleeve 360, sleeve 360 may include entrances (e.g., 362) on one or more sides of the sleeve 360. The entrances may allow interconnects to travers to the interior of sleeve 360, and may generally seal around the interconnects to prevent unfiltered air from traversing into the volume bounded by sleeve 360 (which may then be drawn into the interior of chassis 330 via fans, positive air pressure generated by a ventilation system, etc.). Thus, the filter bezel and volume may form an airflow path through the chassis, while the entrances (e.g., 362) may not be in the airflow path. To prevent airflow through entrance 362, entrance 362 may include, for example, flaps or other strips of material that may be moved out of the way to insert interconnects through the entrance, but that may generally move back into place thereby generally sealing entrance 362.

Thus, using a cable management mount in accordance with an embodiment, interconnects may be routed and secured with respect to data processing systems positioned in challenging environments.

As discussed above, the components of FIGS. 1A-3G may be used to perform various methods to manage routing and securing of interconnects for data processing systems. FIG. 4 illustrates a method that may be performed using the components of the system of FIGS. 1A-3G. In the diagram discussed below and shown in FIG. 4, any of the operations may be repeated, performed in different orders, and/or performed in parallel with or in a partially overlapping in time manner with other operations.

Turning to FIG. 4, a flow diagram illustrating a method for servicing a data processing system in a rack (or other type of enclosure) in accordance with an embodiment is shown. The method may be performed by a technician or other person tasked with connecting the data processing system to other components.

To route and secure interconnects in place, a technician or other person may attach mechanically interlocking side latches to a chassis, a mounting bracket attached to the chassis, to an extension, or to another person of a rack system. The attachment may be completed in a tool free manner. For example, an extension (e.g., 116) attached to a sled (e.g., 112) may include mounting points for mounting brackets and/or the mechanically interlocking side latches. The mounting points may include threaded through holes or other structures to which toolless fixation members of the mounting brackets or mechanically interlocking side latches may be secured.

Once the mechanically interlocking side latches are in place, a spring loaded cross bar may be attached, as illustrated via example in FIGS. 2E-2G.

It will be appreciated that the aforementioned components may be removed in a similar manner (e.g., to remove interconnects, prepare the chassis for transport to another rack/location, etc.).

At operation 400, a first portion of cabling (e.g., of an interconnect) along the rack may be routed to a first position with respect to a data processing system using a mechanically interlocking side latch assembly, cable management mount, or other component of a cable management system. The first portion of the cabling may be routed by positioning the first portion between a first retention member of the mechanically interlocking side latch assembly (or cable management mount) and a second retention member of the mechanically interlocking side latch assembly (e.g., between 208 illustrated in FIG. 2A) or cable management mount. The portion may be positioned by sliding the portion between the retention members (e.g., as opposed to requiring that the first portion of the cabling be threaded through the retention members until the first portion is aligned with the retention members). Once so positioned, the first portion may be secured by actuating the first retention member and the second retention member to circumscribe the first portion of the cabling. The first retention member and the second retention member may then be further actuated (e.g., twisted together) to close the two retention members around the portion of the cabling. Closing the two retention members may increase friction between the first portion and the two retention members thereby reducing a likelihood of the first portion moving with respect to the two retention members. In this manner, any number of portions of cabling may be secured by the mechanically interlocking side latch assembly.

It will be appreciated that other portions of interconnects may be secured by routing to other retention members (e.g., retention member 212, 310, and which may not require tightening, when so positioned in retention member 212, 310 the interior surface may provide sufficient friction to prevent movement of the corresponding portions of the interconnects absent application of force).

As part of the routing process, the cabling may be fed through entrances of sleeves or other structures used to manage challenging environments. Consequently, the secured portions of the routed cabling may be positioned in the interior of the sleeves or other structures.

At operation 402, a second portion of the cabling may be routed, using a spring loaded cross bar of the data processing system positioned between the mechanically interlocking side latch assembly and a second mechanically interlocking side latch assembly (or a pair of cable management mounts), to a second position with respect to the data processing system. The second portion of the cabling may be routed by positioning the second portion of the cabling in proximity to a portion of the spring loaded cross bar. The second portion may be identified via surface features (e.g., texturing) of the spring loaded cross bar and/or positioning of receptacles on a chassis of the data processing system to which the cabling may be attached.

At operation 404, the cabling may be connected to at least one hardware component of the data processing system to establish an interconnect between the at least one hardware component and a second hardware component that is not part of the data processing system. The cabling may be connected by attaching a mating portion (e.g., a connected, which may be threaded, press on, etc.) of the cabling to a receptacle. Connecting the cabling may establish an interconnect between the hardware component (e.g., in the chassis) and another hardware components (e.g., the cabling may attached to another data processing system directly if in the same rack, or may be part of a communication system through which the interconnect may be established to a remote hardware component in a remote data processing system).

As part of the attachment process, multiple cables may be attached to multiple corresponding receptacles. To manage these connections, a first strand of the cabling may be aligned with respect to a second strand of the cabling to obtain aligned strands of the cabling aligning using a node-based cable clip. For example, the two strands may be placed in tracks of the cable clip. The cable clip may then be closed to fixedly secure the cabling in place. Once positioned, the first aligned strand of the cabling may be connected to a receptacle for the at least one hardware component.

At operation 406, the first portion of the cabling may be secured with respect to the first position and the second portion of the cabling may be secured with respect to the second position to manage stress applied to the interconnect. As discussed above, the first portion may be secured using the retention members of the mechanically interlocking side latch assembly or cable management mounts. To secure the second portion of the cabling, a tie may be actuated to circumscribe the second portion of the cabling and the portion of the spring loaded cross bar. Once circumscribed, the tie may be twisted to press the second portion of the cabling and the spring loaded cross bar (e.g., to establish sufficient friction to make movement unlikely without application of force).

The method may end following operation 406.

Thus, using the method shown in FIG. 4, embodiments disclosed herein may facilitate securing of interconnects that may include cabling and/or other linear members without requiring the use of tools.

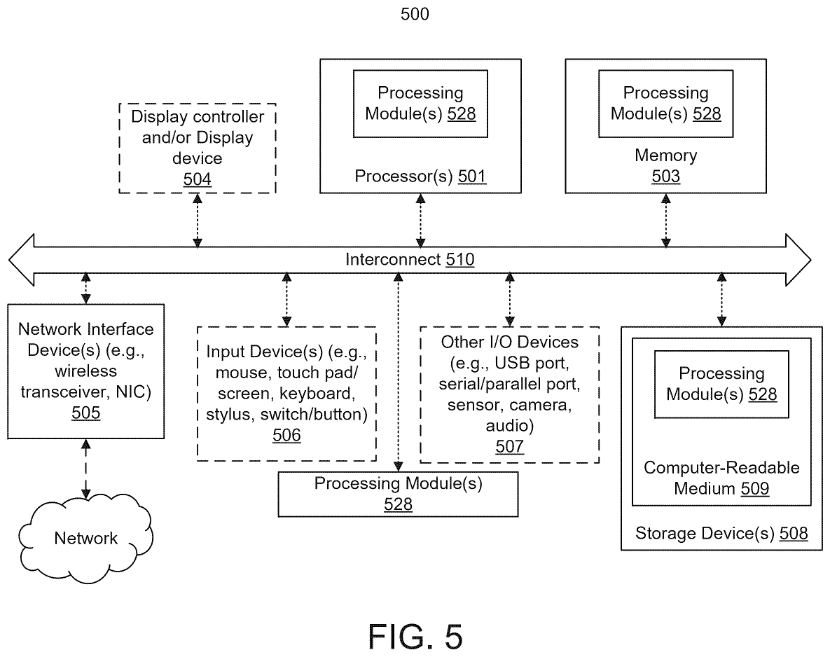

Embodiments disclosed herein may be implemented with one or more computing devices. Turning to FIG. 5, a block diagram illustrating an example of a data processing system (e.g., a computing device) in accordance with an embodiment is shown.

For example, system 500 may represent any of the data processing systems described above performing any of the processes or methods described above. System 500 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 500 is intended to show a high-level view of many components of the computer system. However, it is to be understood that additional components may be present in certain implementations and furthermore, different arrangement of the components shown may occur in other implementations. System 500 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 500 includes processor 501, memory 503, and devices 505-507 via a bus or an interconnect 510. Processor 501 may represent a single processor or multiple processors with a single processor core or multiple processor cores included therein. Processor 501 may represent one or more general-purpose processors such as a microprocessor, a central processing unit (CPU), or the like. More particularly, processor 501 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 501 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 501, which may be a low power multi-core processor socket such as an ultra-low voltage processor, may act as a main processing unit and central hub for communication with the various components of the system. Such processors can be implemented as a system on chip (SoC). Processor 501 is configured to execute instructions for performing the operations discussed herein. System 500 may further include a graphics interface that communicates with optional graphics subsystem 504, which may include a display controller, a graphics processor, and/or a display device.

Processor 501 may communicate with memory 503, which in one embodiment can be implemented via multiple memory devices to provide for a given amount of system memory. Memory 503 may include one or more volatile storage (or memory) devices such as random-access memory (RAM), dynamic RAM (DRAM), synchronous DRAM (SDRAM), static RAM (SRAM), or other types of storage devices. Memory 503 may store information including sequences of instructions that are executed by processor 501, or any other device. For example, executable code and/or data of a variety of operating systems, device drivers, firmware (e.g., input output basic system or BIOS), and/or applications can be loaded in memory 503 and executed by processor 501. An operating system can be any kind of operating systems, such as, for example, Windows® operating system from Microsoft®, Mac OS®/IOS® from Apple, Android® from Google®, Linux®, Unix®, or other real-time or embedded operating systems such as VxWorks.

System 500 may further include IO devices such as devices (e.g., 505, 506, 507, 508) including network interface device(s) 505, optional input device(s) 506, and other optional IO device(s) 507. Network interface device(s) 505 may include a wireless transceiver and/or a network interface card (NIC). The wireless transceiver may be a Wi-Fi transceiver, an infrared transceiver, a Bluetooth transceiver, a WiMAX transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 506 may include a mouse, a touch pad, a touch sensitive screen (which may be integrated with a display device of optional graphics subsystem 504), a pointer device such as a stylus, and/or a keyboard (e.g., physical keyboard or a virtual keyboard displayed as part of a touch sensitive screen). For example, input device(s) 506 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 507 may include an audio device. An audio device may include a speaker and/or a microphone to facilitate voice-enabled functions, such as voice recognition, voice replication, digital recording, and/or telephony functions. Other IO devices 507 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 507 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 510 via a sensor hub (not shown), while other devices such as a keyboard or thermal sensor may be controlled by an embedded controller (not shown), dependent upon the specific configuration or design of system 500.

To provide for persistent storage of information such as data, applications, one or more operating systems and so forth, a mass storage (not shown) may also couple to processor 501. In various embodiments, to enable a thinner and lighter system design as well as to improve system responsiveness, this mass storage may be implemented via a solid-state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also, a flash device may be coupled to processor 501, e.g., via a serial peripheral interface (SPI). This flash device may provide for non-volatile storage of system software, including a basic input/output software (BIOS) as well as other firmware of the system.

Storage device 508 may include computer-readable storage medium 509 (also known as a machine-readable storage medium or a computer-readable medium) on which is stored one or more sets of instructions or software (e.g., processing module, unit, and/or processing module/unit/logic 528) embodying any one or more of the methodologies or functions described herein. Processing module/unit/logic 528 may represent any of the components described above. Processing module/unit/logic 528 may also reside, completely or at least partially, within memory 503 and/or within processor 501 during execution thereof by system 500, memory 503 and processor 501 also constituting machine-accessible storage media. Processing module/unit/logic 528 may further be transmitted or received over a network via network interface device(s) 505.

Computer-readable storage medium 509 may also be used to store some software functionalities described above persistently. While computer-readable storage medium 509 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 528, components and other features described herein can be implemented as discrete hardware components or integrated in the functionality of hardware components such as ASICS, FPGAs, DSPs or similar devices. In addition, processing module/unit/logic 528 can be implemented as firmware or functional circuitry within hardware devices. Further, processing module/unit/logic 528 can be implemented in any combination hardware devices and software components.

Note that while system 500 is illustrated with various components of a data processing system, it is not intended to represent any particular architecture or manner of interconnecting the components as such details are not germane to embodiments disclosed herein. It will also be appreciated that network computers, handheld computers, mobile phones, servers, and/or other data processing systems which have fewer components, or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-SUBSTITUTE readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g., circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A management system for interconnects to operably connect data processing systems, the management system comprising:
a pair of brackets adapted to attach to a chassis;
a sleeve adapted to:
partially enclose a volume extending from the chassis and enclosing the pair of brackets, and
facilitate routing of the interconnects into the volume;
at least one cross bar adapted to:
attach to the pair of brackets, and
while attached to the pair of brackets, secure at least a portion of the interconnects in the volume.

2. The management system of claim 1, further comprising:
an air filtering bezel adapted to partially enclose the volume on a side of the volume opposite to the chassis.

3. The management system of claim 2, wherein the interconnects cannot pass into the volume through the air filtering bezel.

4. The management system of claim 3, wherein the sleeve comprises at least one entrance to pass the interconnects into the volume.

5. The management system of claim 4, wherein the air filtering bezel and the sleeve define an airflow path to the chassis.

6. The management system of claim 5, wherein the at least one entrance is out of the airflow path.

7. The management system of claim 1, wherein the at least one cross bar comprises a plurality of cross bars, and the pair of brackets are adapted to support the plurality of cross bars at different locations with respect to the chassis.

8. The management system of claim 7, wherein the different locations correspond to different sleds in the chassis to secure different ones of the interconnects with respect to the different sleds.

9. The management system of claim 8, wherein the plurality of cross bars are aligned with one another when supported by the pair of brackets.

10. The management system of claim 1, wherein receptacles for attachment of the interconnects are positioned on the chassis and in the volume.

11. The management system of claim 10, wherein the sleeve encloses the volume on four sides, and the chassis enclosed the volume on a fifth side.

12. The management system of claim 1, further comprising a tie adapted to reversibly fixedly secure a portion of the interconnects to the at least one cross bar.

13. A data processing system, comprising:
a chassis; and
a management system for interconnects to operably connect data processing systems, the management system comprising:
a pair of brackets adapted to attach to a chassis;
a sleeve adapted to:
partially enclose a volume extending from the chassis and enclosing the pair of brackets, and
facilitate routing of the interconnects into the volume;
at least one cross bar adapted to:
attach to the pair of brackets, and
while attached to the pair of brackets, secure at least a portion of the interconnects in the volume.

14. The data processing system of claim 13, further comprising:
an air filtering bezel adapted to partially enclose the volume on a side of the volume opposite to the chassis.

15. The data processing system of claim 14, wherein the interconnects cannot pass into the volume through the air filtering bezel.

16. The data processing system of claim 15, wherein the sleeve comprises at least one entrance to pass the interconnects into the volume.

17. The data processing system of claim 16, wherein the air filtering bezel and the sleeve define an airflow path to the chassis.

18. The data processing system of claim 17, wherein the at least one entrance is out of the airflow path.

19. The data processing system of claim 13, wherein the at least one cross bar comprises a plurality of cross bars, and the pair of brackets are adapted to support the plurality of cross bars at different locations with respect to the chassis.

20. The data processing system of claim 19, wherein the different locations correspond to different sleds in the chassis to secure different ones of the interconnects with respect to the different sleds.
